(19) United States
(12) Patent Application Publication
(10) Pub. No.: US 2009/0266602 A1
(43) Pub. Date: Oct. 29, 2009

(54) ELECTROMAGNETIC INTERFERENCE SHIELD

(75) Inventor: Tien-Chung Tseng, Taipei Hsien (TW)

Correspondence Address: PAI PATENT & TRADEMARK LAW FIRM, 1001 FOURTH AVENUE, SUITE 3200, SEATTLE, WA, 98154, US

(73) Assignee: WISTRON CORP., Taipei Hsien (TW)

(21) Appl. No.: 12/178,313

(22) Filed: Jul. 23, 2008

(30) Foreign Application Priority Data
Apr. 23, 2008 (TW) 97114929

(51) Int. Cl. H05K 9/00

(52) U.S. Cl. 174/377

(57) ABSTRACT

This present invention is an electromagnetic interference shield, comprising a shielding cap, an insulator, and an electric conductive paste, wherein protruding edges of the shielding cap are mounted with electric conductive paste on a PCB and the insulator is placed between the shielding cap and the PCB to keep them from touching with each other to provide the EMI prevention to the PCB.

### RELATED APPLICATIONS

This application claims priority to Taiwan Application Serial Number 97114929, filed Apr. 23, 2008, which is herein incorporated by reference.

### BACKGROUND

1. Field of Invention

The presented invention relates generally to an electromagnetic interference shield. More particularly, the presented invention relates to an electromagnetic interference shield disposed on a printed circuit board (PCB) for shielding the electromagnetic interference (EMI)

2. Description of Related Art

Electromagnetic interference shielding is the process of blocking the flow of electromagnetic radiation between two locations, by separating them with a barrier made of conductive material. Typical materials used for electromagnetic shielding include sheet metal, metal mesh, which can be electrically connected to the chassis ground of the electronic equipment, thus providing effective shielding. As shown in FIG. 1, the electromagnetic shielding 10 in the prior art is mounted on the printed circuit board 30 by soldering with tin solder 20 and conductively connected to a predetermined ground line.

However, the assembly of the electromagnetic shielding in the prior art is complicated. For instance, the steps of cleaning the printed circuit board and printing the tin solder on the printed circuit board can not be omitted. And by soldering the electromagnetic shielding 10 on the printed circuit board 30, the assembling height of the whole electromagnetic shielding and the printed circuit board can hardly be reduced. The follow-up maintenance of the printed circuit board soldered with the electromagnetic shielding is also difficult, such that the whole electromagnetic shielding has to be removed to maintain the electronic components beneath the electromagnetic shielding. And the process of removing the electromagnetic shielding may cause deformation and cannot be repeated. Even the removal of the electromagnetic shielding may affect the electronic components on the printed circuit board. Furthermore, the cost of the soldering process is high, and soldering process may cause short-circuit risk of the electronic components on the circuit boards. Therefore, the electromagnetic shielding in the prior art still needs to be improved.

### SUMMARY

For this reason, the invention provides an electromagnetic interference shield with fewer components, less manufacturing cost, and easier structure to assemble on the PCB.

The invention provides an electromagnetic interference shield comprising a shielding cap, an insulator and an electric conductive paste, wherein the shielding cap has an indentation and a protruding edge on the rim of the indentation. The shielding cap covers the PCB with its indentation and provides electromagnetic interference prevention to the PCB. The insulator is disposed in the indentation to support the indentation of the shielding cap on the PCB and to prevent the covered area on the PCB from touching the shielding cap. The electric conductive paste is glued on one side of the protruding edge to seal the shielding cap on the PCB. And the electric conductive paste also provides a conducting circuit route for the shielding cap to shield the electromagnetic interference to the PCB.

Furthermore, the shielding cap is not limited in shape but corresponds to the shielding area of the electronic components on the PCB. The shielding cap of this invention can comprise a metal material, i.e. an aluminum foil shell, or a plastic shell with a metal shielding layer covered on the inner surface thereof. And the thickness of the metal shielding layer covered on the plastic shell can be designed corresponding to the requirement of the EMI prevention design specification.

The protruding edge of the shielding cap is glued with the electrical conductive paste to seal the shielding cap on the PCB. Therefore, the total assembling height of the shielding cap and the PCB can be reduced. And the assembly of the shielding cap and the PCB is simplified by fewer components and easier structure of the electromagnetic interference shield. The electromagnetic interference shield of the invention can even reduce the manufacturing costs of the simple electromagnetic interference shield structure.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is an electromagnetic shielding as in the prior art;

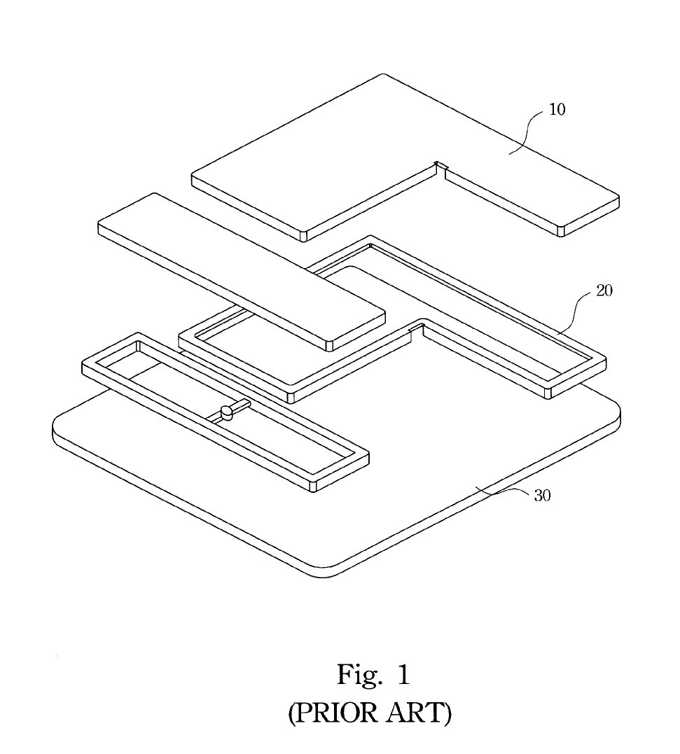

FIG. 2 illustrates the components of the preferred embodiment of the electromagnetic interference shield of this invention;

FIG. 3 illustrates the sectional drawing of the electromagnetic interference shield of this invention; and

FIG. 4 illustrates the shielding cap of the electromagnetic interference shield of this invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

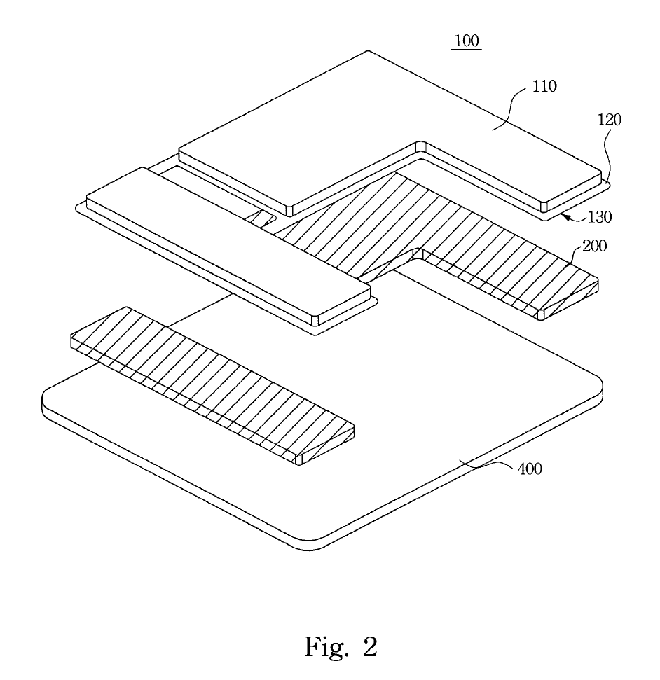

Refer to FIG. 2. FIG. 2 illustrates the preferred embodiment of the electromagnetic interference shield of this invention. As shown in FIG. 2, the electromagnetic interference shield 100 of the invention is covered on the PCB 400 and protects the electrical components on the PCB 400 from being disrupted by electromagnetic interference (EMI). The electromagnetic interference shield 100 comprises a shielding cap 110, an insulator 200, and an electrical conductive paste 300 (not shown this the figure). The shielding cap 110 has an indentation 130 and a protruding edge 120 on the rim of the indentation 130. The shielding cap 110 covers the PCB 400 with the indentation 130 to provide electromagnetic interference prevention to the PCB 400.

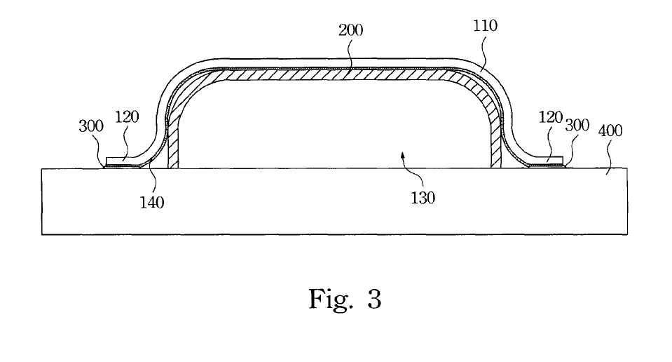

Refer to FIG. 3. FIG. 3 illustrates the sectional drawing of the electromagnetic interference shield of this invention. As shown in FIG. 3, the insulator 200 is disposed in the indentation 130 of the shielding cap 110, and the indentation 130 covers the PCB 400, wherein the shape of the insulator 200 conforms to the indentation 130. The insulator 200 separates the shielding cap 110 and the PCB 400 and keeps them from touching each other to prevent short circuits induced between electronic components on the PCB 400. The protruding edge 120 of the shielding cap 110 is pasted on the PCB 400 with the electric conductive paste 300, so the shielding cap 110 is sealed and covered on the PCB 400, as shown in FIG. 3. The electrical conductive paste 300 also provides a conducting circuit route for the shielding cap 110 to provide the electromagnetic interference prevention to the PCB 400. The volume of the above-mentioned insulator 200 can be equal to or less than the volume of the indentation 130 and the height of the insulator 200 can be equal to or less than the depth of the indentation 130 to install the insulator 200 in the indentation 130. That is, the required volume and the height of the insulator 200 are applied to keep the shielding cap 110 from touching the PCB 400, such that the insulator 200 can contact both the shielding cap 110 and the PCB 400 to support the indentation 130 of the shielding cap 110 on the PCB 400, or the insulator 200 can contact only one of the shielding cap 110 and the PCB 400 to support the indentation 130 of the shielding cap 110 on the PCB 400. The insulator 200 disposed between the shielding cap 110 and the PCB 400 can prevent the area on the PCB 400, which is covered by the indentation 130, from touching the shielding cap 110, to prevent a short circuit between the electronic components on the PCB 400.

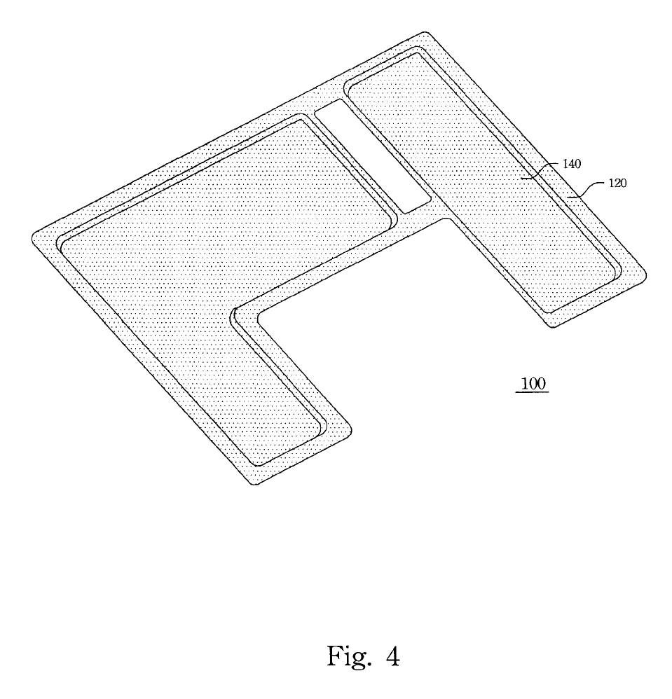

Refer to FIG. 4. FIG. 4 illustrates the shielding cap of the electromagnetic interference shield of this invention. The shielding cap 110 of this invention can apply a metal material, i.e. an aluminum foil shell. Or, as shown in FIG. 4, the shielding cap 110 can apply a plastic shell with a metal shielding layer 140 coated on the inner surface thereof to provide the EMI prevention. And the thickness of the metal shielding layer 140 coated on the inner surface of the shielding cap 110 can be designed corresponding to the requirement of the EMI prevention specification. Nevertheless, the shielding cap 110 is not limited in shapes but corresponds to the shielding area of the electronic components on the PCB 400.

Therefore, by this invention, an electromagnetic interference shield with fewer components, less manufacturing cost, and easier structure to assemble on the PCB is provided.

Although the present invention has been described in considerable detail with reference certain embodiments thereof, other embodiments are possible. Therefore, their spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1-7. (canceled)

8. An electromagnetic interference shield, comprising:
a shielding cap having a plastic shell with an indentation and a protruding edge on the rim of the indentation, wherein the indentation covers on a printed circuit board (PCB);
a metal shielding layer coated on an inner surface of the indentation to provide the electromagnetic interference prevention to the PCB:
an insulator disposed in the indentation to support the indentation of the plastic shell on the PCB, wherein the insulator has a shape conforming to the indentation; and
an electrical conductive paste being glued on one side of the protruding edge and attaching the shielding cap on the PCB.

9. The electromagnetic interference shield of claim 8, wherein the insulator contacts both the shielding cap and the PCB to support the indentation of the shielding cap on the PCB.

10. The electromagnetic interference shield of claim 8, wherein the insulator contacts only one of the shielding cap and the PCB to support the indentation of the shielding cap on the PCB.

11-13. (canceled)
